(19) United States
(12) Patent Application Publication
(10) Pub. No.: US 2026/0123019 A1
(43) Pub. Date: Apr. 30, 2026

(54) SURFACE PROFILE CONTROL OF EPITAXIAL REGIONS IN SEMICONDUCTOR DEVICES

(71) Applicant: Taiwan Semiconductor Manufacturing Company, Ltd., Hsinchu (TW)

(72) Inventors: I-Han HUANG, Taipei City (TW); Chu-Yuan Hsu, Taichung City (TW); Jia-Chuan You, Taoyuan (TW); Chia-Hao Chang, Hsinchu (TW); Kuo-Cheng Chiang, Hsinchu (TW)

(73) Assignee: Taiwan Semiconductor Manufacturing Company, Ltd., Hsinchu (TW)

(21) Appl. No.: 19/190,208

(22) Filed: Apr. 25, 2025

Related U.S. Application Data
(60) Provisional application No. 63/712,667, filed on Oct. 28, 2024.

(51) Int. Cl. H10D 84/01; H10D 30/00

(52) U.S. Cl. CPC H10D 84/013; H10D 30/501; H10D 84/0149

(57) ABSTRACT

A semiconductor structure and a method of fabricating the structure are disclosed. The method includes forming a superlattice structure with a nanostructured layer and a sacrificial nanostructured layer on a base structure on a substrate, forming a polysilicon structure on the superlattice structure, and forming a S/D region in the superlattice structure. A S/D portion of the S/D region extends above the nanostructured layer. The method further includes modifying a thickness of the S/D portion, depositing a dielectric layer on the modified S/D portion, and replacing the polysilicon structure and the sacrificial nanostructured layer with a gate structure.

### CROSS-REFERENCE TO RELATED APPLICATIONS

This application claims the benefit of U.S. Provisional Patent Application No. 63/712,667, titled “Epitaxial Structures in Semiconductor Devices,” filed Oct. 28, 2024, which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1 illustrates an isometric view of a semiconductor device, in accordance with some embodiments.

FIGS. 1B-1H illustrate different cross-sectional views of a semiconductor device, in accordance with some embodiments.

FIG. 2 is a flow diagram of a method for fabricating a semiconductor device, in accordance with some embodiments.

FIGS. 3A-14A, 3B-14B, and 3C-14C illustrate isometric and cross-sectional views of a semiconductor device at various stages of its fabrication process, in accordance with some embodiments.

FIGS. 15 and 16 illustrate cross-sectional views of another semiconductor device at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GA A transistor structure.

A GAA FET can include first and second fin-shaped base structures disposed on a substrate, first and second stacks of nanostructured channel regions disposed on the first and second fin-shaped base structures, respectively, a source/drain (S/D) region disposed between the first and second stacks of nanostructured channel regions, and first and second gate structures surrounding the nanostructured channel regions in the first and second stacks of nanostructured channel regions, respectively. The S/D region is epitaxially formed along sidewalls of the nanostructured channel regions facing the S/D region. To ensure adequate sidewall coverage of the nanostructured channel regions by the S/D region, the S/D region is extended above top surfaces of the topmost nanostructured channel regions. As a result, the extended portion of the S/D region overlaps with the adjacent gate structures along a vertical cross-sectional plane, which increases the challenges of minimizing parasitic capacitance between the S/D region and the gate structures.

To address the abovementioned challenges, the present disclosure provides example GAA FETs with reduced parasitic capacitance between a gate structure and a S/D region and examples methods of fabricating these GAA FETs. In some embodiments, the formation of the S/D region can be followed by an etching process on the S/D region to reduce the thickness of the extended S/D portion without compromising the sidewall coverage of the nanostructured channel regions by the S/D region. In some embodiments, to ensure adequate sidewall coverage of the nanostructured channel regions by the S/D region, the etching process can be controlled to achieve W-shaped or concave-shaped cross-sectional profiles (also referred to as “etch profiles”) along vertical cross-sectional planes (e.g., XZ and YZ planes) for the S/D top surface. In some embodiments, for the W-shaped or concave-shaped cross-sectional profiles of the S/D top surface extending between adjacent nanostructured channel regions, the edges of the S/D top surface can be raised above the top surfaces of the topmost nanostructured channel regions and the middle portion of the S/D top surface can have a convex-shaped or a concave-shaped profile. In some embodiments, during the etching process, the thickness of the extended S/D portion can be reduced from a first thickness of about 4 nm to about 12 nm to a second thickness of about 2 nm to about 8 nm. Such reduction in the thickness of the extended S/D portion can result in the reduction of the parasitic capacitance between the S/D region and the gate structures by about 2% to about 3%. In some embodiments, reducing the thickness of the extended S/D portion can also facilitate the formation of gate structures with shorter heights, which facilitates the scaling down of GAA FETs to meet the increasing demand for small and portable semiconductor devices.

In some embodiments, the etching process can be followed by the formation of a etch control layer (e.g., silicon nitride (SiN) layer; also referred to as “a hard mask layer”) on the S/D top surface and on top surfaces of an etch stop layer and interlayer dielectric layer disposed on the S/D region. The etch control layer can preserve the integrity of the edge profiles of the S/D top surface during subsequent processes on the S/D region. In some embodiments, the etch control layer can also facilitate the formation of deep contact opening in the S/D region while preventing the etch stop layer and interlayer dielectric layer from being over-etched during the formation of the contact opening. As a result, a contact structure on the S/D region can be formed with a larger contact area with the S/D region, while the portion of the contact structure on the etch stop layer and interlayer dielectric layer can have a depth less than that formed without the barrier layer on the S/D region. In some embodiments, due to such shallow depth of the contact structure, the parasitic capacitance between the S/D region and the portion of the contact structure on the etch stop layer and interlayer dielectric layer can be reduced by about 1% to about 4%. Thus, the overall parasitic capacitance of the GAA FET can be reduced by about 3% to about 7%.

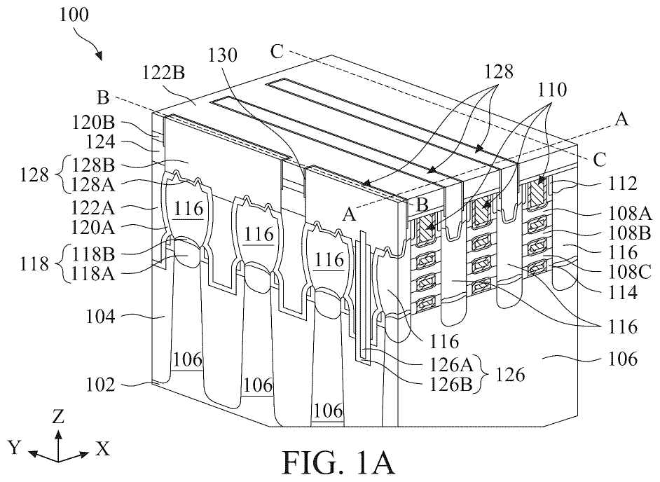

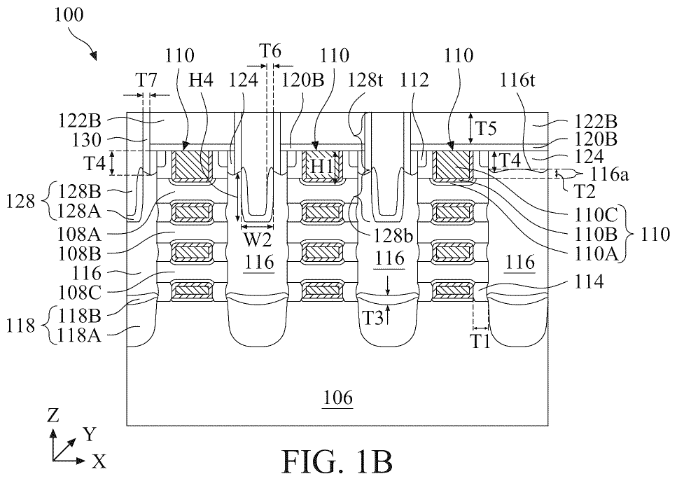

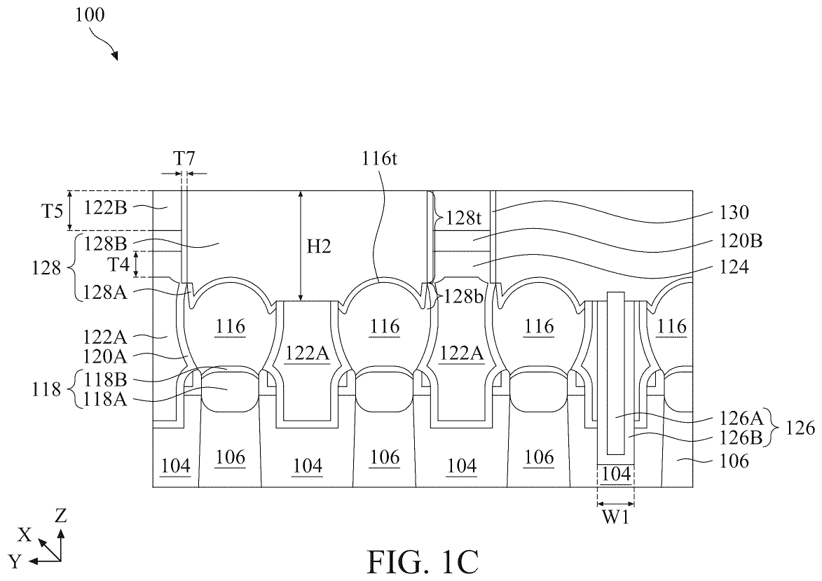

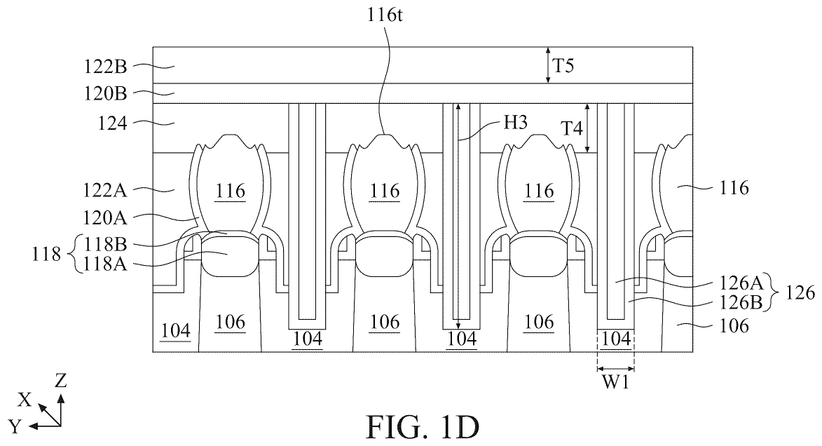

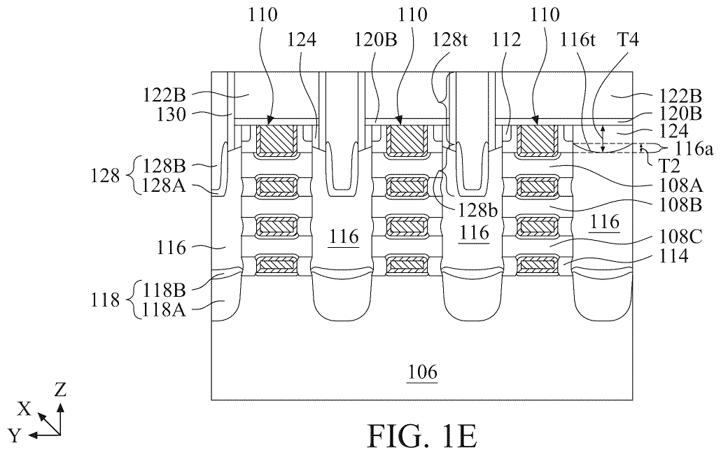

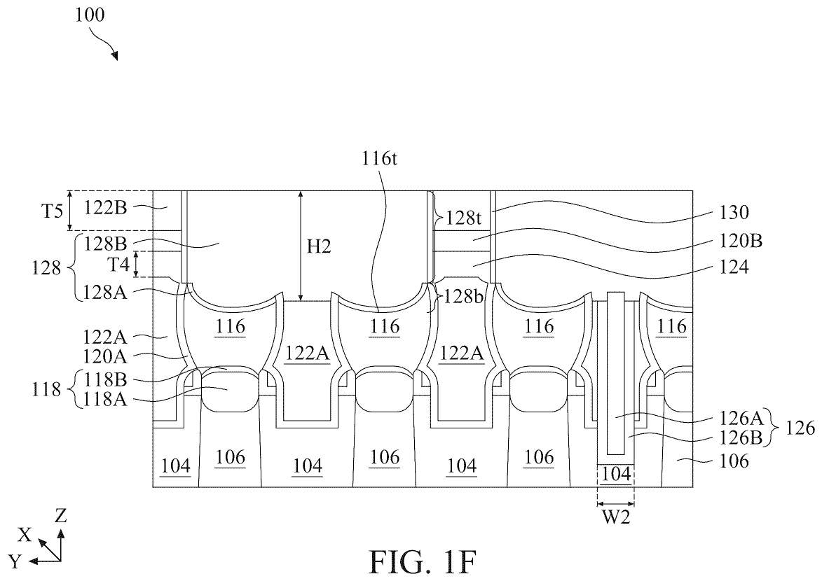

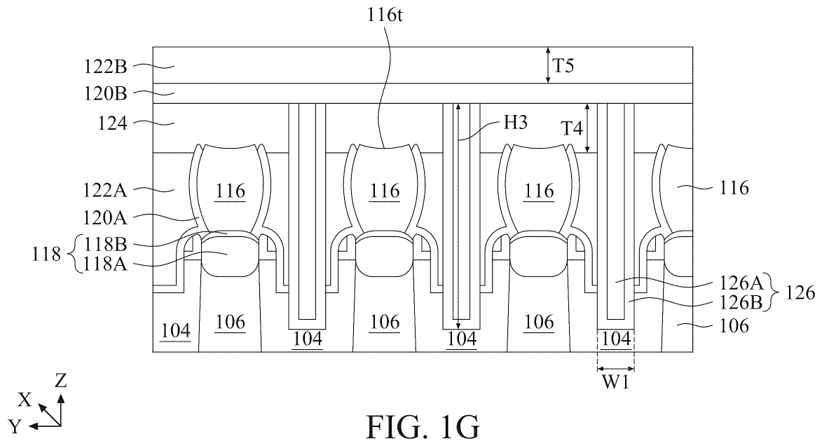

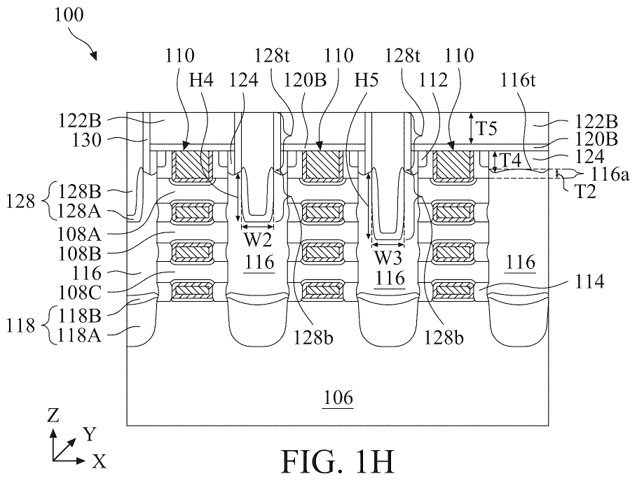

FIG. 1A illustrates an isometric view of a semiconductor device 100, which can represent a GAA FET 100, according to some embodiments. FIGS. 1B, 1E, and 1H illustrate different cross-sectional views of GAA FET 100 along line A-A of FIG. 1A, with additional structures that are not shown in FIG. 1A for simplicity, according to some embodiments. FIGS. 1C and 1F illustrate different cross-sectional views of GAA FET 100 along line B-B of FIG. 1A, with additional structures that are not shown in FIGS. 1A and 1B for simplicity, according to some embodiments. FIGS. 1D and 1G illustrate different cross-sectional views of GAA FET 100 along line C-C of FIG. 1A, with additional structures that are not shown in FIG. 1A for simplicity, according to some embodiments. The discussion of elements in FIGS. 1A-1H with the same annotations applies to each other, unless mentioned otherwise.

Referring to FIGS. 1A-1H, in some embodiments, GAA FET 100 can include (i) a substrate 102 (shown in FIG. 1A; not shown in FIGS. 1B-1H for simplicity), (ii) STI regions 104 (not visible in cross-sectional views of FIGS. 1B, 1E, and 1H) disposed on substrate 102, (iii) fin-shaped base structures 106 (also referred to as “sheet bases 106” or “fin bases 106”) disposed on substrate 102, (iv) stacks of nanostructured channel regions 108A-108C disposed on each of fin-shaped base structures 106A-106D (not visible in cross-sectional views of FIGS. 1C, 1D, 1F, and 1G, (v) gate structures 110 (also referred to as “GAA structures 110”; not visible in cross-sectional views of FIGS. 1C, 1D, 1F, and 1G) surrounding nanostructured channel regions 108A-108C, (vi) outer gate spacers 112 (not visible in cross-sectional views of FIGS. 1C, 1D, 1F, and 1G), (vii) inner gate spacers 114 (not visible in cross-sectional views of FIGS. 1C, 1D, 1F, and 1G), (viii) S/D regions 116, (ix) interposing layers 118, (x) etch stop layers (ESLs) 120A and 120B (ESL 120A not visible in cross-sectional views of FIGS. 1B, 1E, and 1H), (xi) interlayer dielectric (ILD) layers 122A and 122B (ILD layer 122A not visible in cross-sectional views of FIGS. 1B, 1E, and 1H), (xii) etch control layers 124 (also referred to as “hard mask layers 124”), (xiii) device isolation structures 126 (also referred to as “cut-metal gate (CMG) structures 126”; not visible in cross-sectional views of FIGS. 1B, 1E, and 1H), (xiv) contact structures 128, and (xv) dielectric layers 130. Each of S/D regions 116 may refer to a source or a drain, individually or collectively dependent upon the context.

In some embodiments, substrate 102 can be a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic). In some embodiments, STI regions 104 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ). In some embodiments, fin-shaped base structures 106 can include a material similar to substrate 102. Fin-shaped base structures 106 can have elongated sides extending along an X-axis.

In some embodiments, nanostructured channel regions 108A-108C can be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. Nanostructured channel regions 108A-108C can include semiconductor materials similar to or different from substrate 102. In some embodiments, nanostructured channel regions 108A-108C can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. In some embodiments, each of nanostructured channel regions 108A-108C can have a thickness of about 3 nm to about 15 nm along a Z-axis. Though three nanostructured channel regions 108A-108C are shown in each stack, GAA FET 100 can have any number of nanostructured channel regions. Though rectangular cross-sections of nanostructured channel regions 108A-108C are shown, nanostructured channel regions 108A-108C can have cross-sections of other geometric shapes (e.g., circular, elliptical, triangular, or polygonal).

Each of gate structures 110 can be a multi-layered structure and can surround nanostructured channel regions 108A-108C for which gate structures 110 can be referred to as “GAA structures.” Each gate structure 110 can include (i) an interfacial oxide (IL) layer 110A, (ii) a high-k (HK) gate dielectric layer 110B, and (iii) a conductive layer 110C. In some embodiments, IL layer 110A can be disposed directly on topmost nanostructured channel regions 108A. In some embodiments, IL layer 110A can include SiO₂, SiGeOₓ, or germanium oxide (GeOₓ) and can have a thickness of about 0.5 nm to about 2 nm. In some embodiments, HK gate dielectric layer 110B can be disposed directly on IL layer 110A and can have a thickness of about 1 nm to about 3 nm. In some embodiments, HK gate oxide layer 110B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). In some embodiments, the sidewalls of IL layer 110A and HK gate oxide layer 110B can be in contact with sidewalls of outer gate spacers 112 and inner gate spacers 114.

In some embodiments, conductive layer 110C can be disposed on HK gate dielectric layer 110B and can be multi-layered structures. The different layers of conductive layer 110C are not shown for simplicity. In some embodiments, conductive layer 110C can include a work function metal (WFM) layer disposed on HK gate dielectric layer 110B and a gate metal fill layer disposed on the WFM layer. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu). In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TIN, Al-doped Ta, Al-doped TaN, or other suitable Al-based materials. In some embodiments, the gate metal fill layer can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Outer gate spacers 112 can electrically isolate gate structures 110 from adjacent S/D regions 116 and contact structures 128. Inner gate spacers 114 can electrically isolate gate portions between nanostructured channel regions 108A-108C from adjacent S/D regions 116. In some embodiments, each of inner gate spacers 114 can have a thickness T1 of about 4 nm to about 6 nm. Within this range of thickness, inner gate spacers 114 can adequately electrically isolate gate portions from adjacent S/D regions 116 without compromising the device size and manufacturing cost. In some embodiments, outer gate spacers 112 and inner gate spacers 114 can include a dielectric material, such as SiO₂, SiN, SiON, SiCN, and SiOCN.

In some embodiments, S/D regions 116 can include an epitaxially-grown semiconductor material, such as Si, and n-type dopants, such as phosphorus and other suitable n-type dopants for n-type GAA FET 100. S/D regions 116 can include an epitaxially-grown semiconductor material, such as Si and SiGe, and p-type dopants, such as boron and other suitable p-type dopants for p-type GAA FET 100.

In some embodiments, S/D regions 116 are epitaxially formed along sidewalls of nanostructured channel regions 108A-108C, as shown in FIGS. 1A, 1B, 1E, and 1H. To ensure adequate sidewall coverage of topmost nanostructured channel regions 108A by S/D regions 116 for adequate conductivity between them, S/D regions 116 are extended above top surfaces of topmost nanostructured channel regions 108A. As a result, extended S/D portions 116a overlap with adjacent conductive layers 110C of gate structures 110 along a vertical cross-sectional plane (e.g., XZ-plane), which can lead to parasitic capacitance between gate structures 110 and S/D regions 116. To prevent or minimize such parasitic capacitance between gate structures 110 and S/D regions 116, thickness T2 of extended S/D portions 116a can be about 2 nm to about 8 nm. In some embodiments, if thickness T2 is below about 2 nm, sidewalls of topmost nanostructured channel regions 108A may not be adequately covered by S/D regions 116, thus degrading the performance of GAA FET 100. On the other hand, if thickness T2 is above about 8 nm, the overlapping regions between gate structures 110 and S/D regions 116 increases, and consequently increases parasitic capacitance between gate structures 110 and S/D regions 116 by about 2% to about 3% or more. In addition, if thickness T2 is above about 8 nm, forming gate structures 110 with shorter heights for scaling down GAA FET 100 to meet the increasing demand for small and portable semiconductor devices becomes challenging. By having thickness T2 of extended S/D portions 116a within the range of about 2 nm to about 8 nm, heights of gate structures 110 can be reduced from a height of about 12 nm to about 16 nm to a height H1 of about 8 nm to about 12 nm while reducing the parasitic capacitance between gate structures 110 and S/D regions 116 by about 2% to about 3% or more.

In some embodiments, to further ensure adequate sidewall coverage of topmost nanostructured channel regions 108A by S/D regions 116, S/D top surfaces 116t of S/D regions 116 can be formed with W-shaped cross-sectional profiles (also referred to as “etch profiles”) along vertical cross-sectional planes (e.g., XZ and YZ planes), as shown in FIGS. 1A-1D and 1H. In some embodiments, instead of W-shaped cross-sectional profiles, S/D top surfaces 116t can be formed with concave-shaped cross-sectional profiles along vertical cross-sectional planes (e.g., XZ and YZ planes), as shown in FIGS. 1E-1G. For the W-shaped or concave-shaped cross-sectional profiles of S/D top surfaces 116t along XZ-planes, the edges of S/D top surfaces 116t can be raised above the top surfaces of topmost nanostructured channel regions 108A and the middle portions of S/D top surfaces 116t can have convex-shaped or concave-shaped profiles.

In some embodiments, interposing layers 118 can be disposed under S/D regions 116 and in recessed regions of fin-shaped base structures 106. In some embodiments, interposing layers 118 can prevent the diffusion of dopants from S/D region 116 to fin-shaped base structures 106, thus preventing current leakage between adjacent S/D regions 116 and short channel effects in GAA FET 100. In some embodiments, interposing layer 118 can be multiple layers which includes an undoped semiconductor layer 118A and a dielectric layer 118B. In some embodiments, interposing layer 118 can be an undoped semiconductor layer or a dielectric layer. The undoped semiconductor layer can be an undoped silicon or silicon-germanium layer.

In some embodiments, undoped semiconductor layers 118A can be disposed in the recessed regions of fin-shaped base structures 106. In some embodiments, undoped semiconductor layers 110A can include undoped silicon or other suitable undoped semiconductor material. In some embodiments, undoped semiconductor layers 118A can extend a distance of about 20 nm to about 40 nm into fin-shaped base structures 106. In some embodiments, if the distance is below about 20 nm, undoped semiconductor layers 111A may not adequately prevent the diffusion of dopants from S/D regions 116 to fin-shaped base structures 106. On the other hand, if the distance is above about 40 nm, the processing time (e.g., etching time, deposition time) for forming undoped semiconductor layers 118A increases, and consequently increases the manufacturing cost of GAA FET 100.

In some embodiments, dielectric layers 118B can be disposed directly on undoped semiconductor layers 118A and along sidewalls of the bottommost inner spacers 114. In some embodiments, each dielectric layer 111B can include a nitride material, such as SiN, SiO₂, SiON, SiCON, SiOC, and SiCN. In some embodiments, each dielectric layer 118B can include a silicon-rich dielectric material. In some embodiments, the silicon-rich dielectric material can include (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, (iv) silicon-rich oxycarbon nitride (Si_{w}OₓC_{y}N_{z}) with a concentration of silicon atoms higher than the concentrations of oxygen atoms, carbon atoms, and nitrogen atoms, (v) silicon-rich boron oxynitride (Si_{w}BₓO_{y}N_{z}) with a concentration of silicon atoms higher than the concentrations of oxygen atoms, boron atoms, and nitrogen atoms, (vi) silicon-rich boron oxycarbide (Si_{w}BₓO_{y}C_{z}) with a concentration of silicon atoms higher than the concentrations of oxygen atoms, boron atoms, and carbon atoms, or (vii) other suitable silicon-rich nitride- or carbide-based dielectric materials. The silicon-rich dielectric material of dielectric layer 118B can provide a high etch resistance to dielectric layer 118B during the formation of dielectric layer 118B. In some embodiments, each dielectric layer 118B can have a thickness T3 of about 2 nm to about 8 nm. Within this range of thickness, dielectric layers 118B can adequately prevent the diffusion of dopants from S/D regions 116 to semiconductor layers 111A without compromising the device size and manufacturing cost of GAA FET 100.

In some embodiments, (i) ESLs 120A can be disposed directly on S/D regions 116 and STI regions 104, (ii) ILD layers 122A can be disposed directly on ESLs 120A, (iii) ESLs 120B can be disposed directly on etch control layers 124, gate structures 110, outer gate spacers 112, dielectric layers 130, and can surround contact structures 128, and (iv) ILD layers 122B can be disposed directly on ESLs 120B and dielectric layers 130 and can surround contact structures 128. In some embodiments, ESLs 120A and 120B can have a thickness of about 3 nm to about 6 nm. In some embodiments, ILD layers 122B can have a thickness T5 of about 10 nm to about 20 nm. In some embodiments, ESLs 120A and 120B and ILD layers 122A and 122B can include dielectric material, such as SiO₂, SiN, SiON, SiCN, SiOC, and SiOCN.

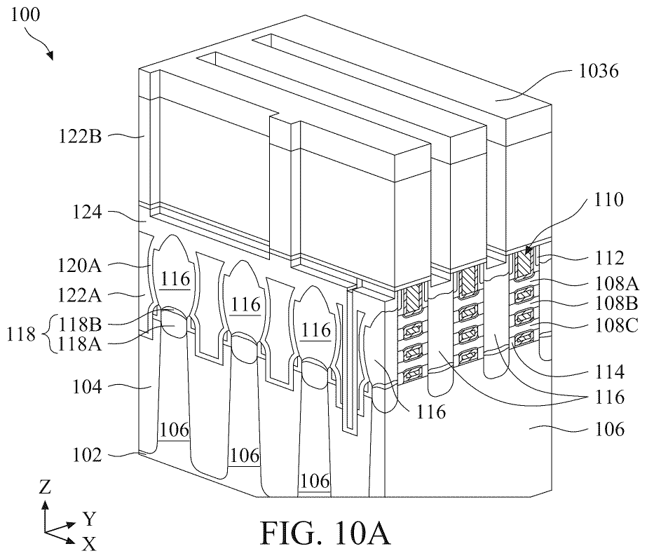

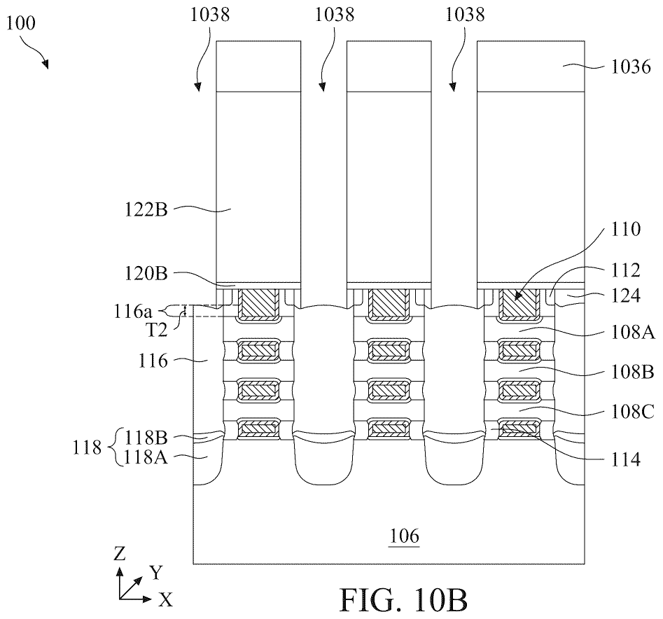

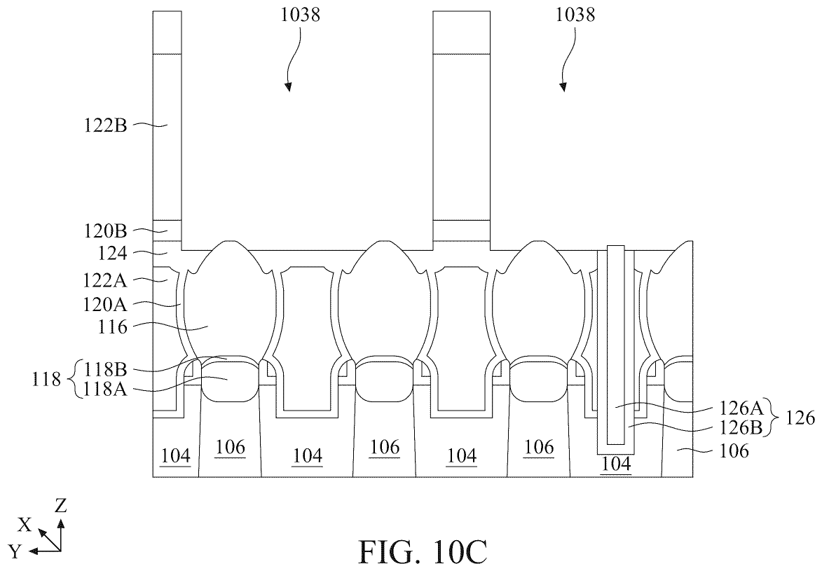

In some embodiments, etch control layers 124 can be disposed directly on (i) S/D top surfaces 116t, (ii) top surfaces of ESLs 120A, and (iii) top surfaces of ILD layers 122A. Etch control layers can be used to control the etch profiles of contact openings 1038 (described below with reference to FIGS. 10A-10C) in S/D regions 116. In addition, etch control layers 124 can be used to prevent dielectric layers 130 from being formed around portions of contact structures 128 in S/D regions 116. The presence of dielectric layers 130 around portions of contact structures 128 in S/D regions can create unwanted barriers for electron conduction between contact structures 128 and topmost nanostructured channel regions 108A. Thus, with the use of etch control layers 124, electrical conductivity between contact structures 128 and topmost nanostructured channel regions 108A can be improved. Furthermore, etch control layers 124 can be used to control the heights of portions of contact structures 128 formed on ESLs 120A and ILD layers 122A between adjacent S/D regions 116, as described in detail below. By controlling these heights, the parasitic capacitance between these portions of contact structures 128 and S/D regions 116 can be controlled. In some embodiments, with the use of etch control layers 124, portions of contact structures 128 on ESLs 120A and ILD layers 122A can be formed with a height H2 of about 15 nm to about 65 nm to reduce the parasitic capacitance between these portions of contact structures 128 and S/D regions 116 by about 1% to about 4%. In some embodiments, etch control layers 124 can have a thickness T4 of about 4 nm to about 14 nm. Within this range of thickness T4, etch control layers 124 can adequately (i) control the etch profiles of contact openings 1038, (ii) prevent dielectric layers 130 from being formed in S/D regions 116, and (iii) control the heights of contact structures 128 formed on ESLs 120A and ILD layers 122A without compromising the device size and manufacturing cost of GAA FET 100. In some embodiments, etch control layers 124 can include a dielectric material different from the dielectric materials of ESLs 120A and 120B. In some embodiments, etch control layers 124 can include SiN layers.

In some embodiments, in addition to gate spacers 112, ESLs 120A, and ILD layers 122A, gate structures 110 can be electrically isolated from each other by device isolation structures 126 to provide independently-controlled gate structures. Device isolation structures 126 can be formed in a cut-metal-gate (CMG) process to cut long gate structures (e.g., along a Y-axis) into shorter gate structures, such as gate structures 110. In some embodiments, each device isolation structure 126 can include an oxide fill layer 126A and a nitride liner 126B surrounding oxide fill layer 126A. In some embodiments, oxide fill layers 126A can include SiO₂ or SiO₂-based material (e.g., silicon oxycarbide) and nitride liners 126B can include SiN material. In some embodiments, each device isolation structure 126 can include a width W1 of about 21 nm to about 33 nm and a height H3 of about 110 nm to about 160 nm. Within these ranges of width W1 and height H3, device isolation structures 126 can adequately provide electrical isolation to gate structures 110 from each other without compromising the device size and manufacturing cost of GAA FET 100.

In some embodiments, contact structure 128 can be disposed on one or more S/D regions 116 of GAA FET 100, as shown in FIGS. 1A, 1B, 1C, 1E, 1F, and 1H. Some S/D regions 116 may not have contact structures 128 disposed on them, as shown in FIGS. 1D and 1G. In some embodiments, first contact portions 128t (also referred to as “top contact portions 128t”) of contact structures 128 can extend above S/D top surfaces 116t and second contact portions 128b (also referred to as “bottom contact portions 128b”) of contact structures 128 can extend below S/D top surfaces 116t. In some embodiments, top contact portions 128t can be surrounded by dielectric layers 130 and bottom contact portions 128b can be surrounded by S/D regions 116. In some embodiments, each bottom contact portion 128b can have a height H4 of about 1 nm to about 45 nm and a width W2 of about 10 nm to about 16 nm along an XZ-plane. Within these ranges of height H4 and width W2, a large contact area can be formed between contact structures 128 and S/D regions 116 without compromising the device size and manufacturing cost of GAA FET 100. In some embodiments, bottom contact portions 128b of different contact structures 128 can have the same height H4 and width W2, as shown in FIGS. 1B and 1E. In some embodiments, bottom contact portions 128b of different contact structures 128 can have heights and widths different from each other, as shown in FIG. 1H. For example, bottom contact portions 128b of one of the contact structures 128 can have height H4 and width W2 and bottom contact portions 128b of another one of the contact structures 128 can have a height H5 and a width W3, as shown in FIG. 1H. In some embodiments, height H5 can be greater than height H4 and width W3 can greater than width W2.

In some embodiments, each contact structure 128 can include (i) a silicide layer 128A disposed in S/D region 116, and (ii) a conductive layer 128B disposed on silicide layer 128A. In some embodiments, each silicide layer 128A can have (i) a thickness T6 of about 2 nm to about 6 nm, (ii) a U-shaped cross-sectional profile along an XZ-plane (shown in FIGS. 1B, 1E, and 1H), and (iii) a W-shaped cross-sectional profile along a YZ-plane (shown in FIG. 1C) or a concave-shaped cross-sectional profile along a YZ-plane (shown in FIG. 1F). In some embodiments, silicide layers 128A in n-type GAA FET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ytterbium silicide (YbₓSi_{y}), europium silicide (EuₓSi_{y}), thorium silicide (ThₓSi_{y}), other suitable metal silicide materials, or a combination thereof. In some embodiments, silicide layer 124A in p-type GAA FET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, conductive layers 128B can include conductive materials, such as Co, W, Ru, Al, Mo, Ir, Ni, Osmium (Os), rhodium (Rh), other suitable conductive materials, and a combination thereof.

In some embodiments, dielectric layers 130 can be disposed on S/D top surfaces 116t and surrounding top contact portions 128t. Dielectric layers 130 can prevent or minimize (i) the diffusion of oxygen atoms from ILD layers 122B into conductive layers 128B, and (ii) the diffusion of metal atoms from conductive layers 128B into gate structures 110. In some embodiments, dielectric layers 130 can include oxygen-free dielectric nitride layers (e.g., SiN layers), oxygen-free dielectric carbide layers (e.g., silicon carbide (SiC) layers), or oxygen-free carbon nitride layers (e.g., silicon carbon nitride (SiCN) layers). In some embodiments, dielectric layers 130 can have a thickness T7 of about 1 nm to about 3 nm to adequately prevent or minimize (i) the diffusion of oxygen atoms from ILD layers 122B into conductive layers 128B, and (ii) the diffusion of metal atoms from conductive layers 128B into gate structures 110.

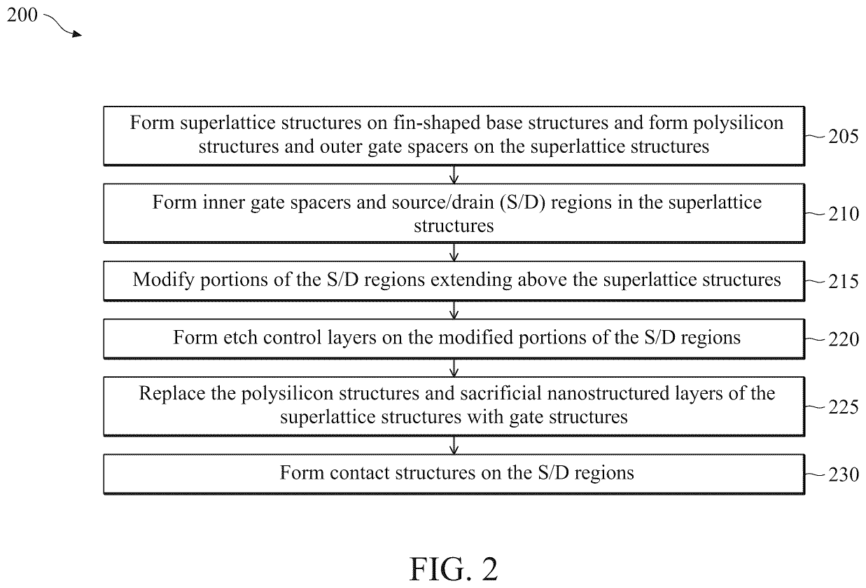

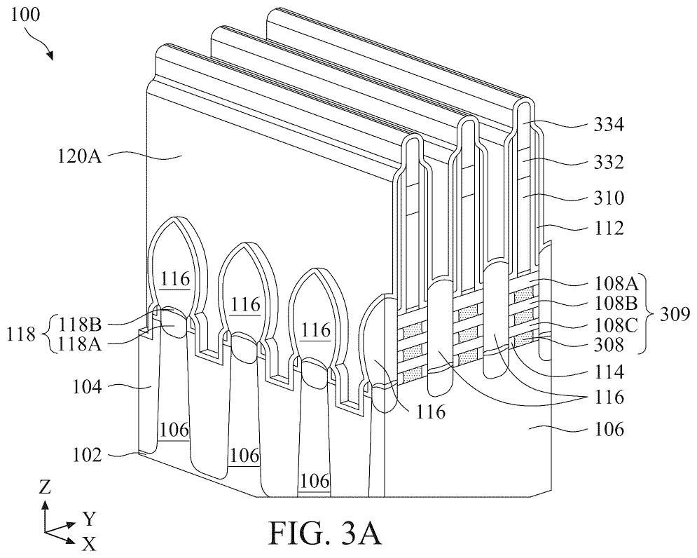

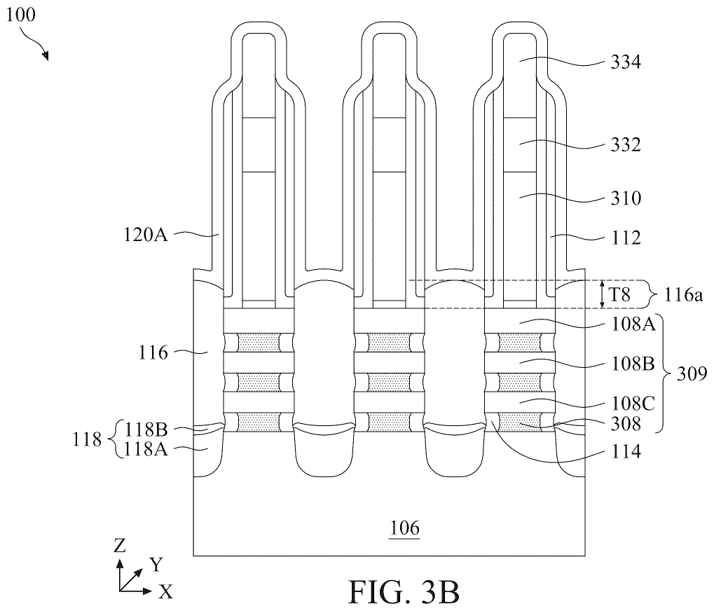

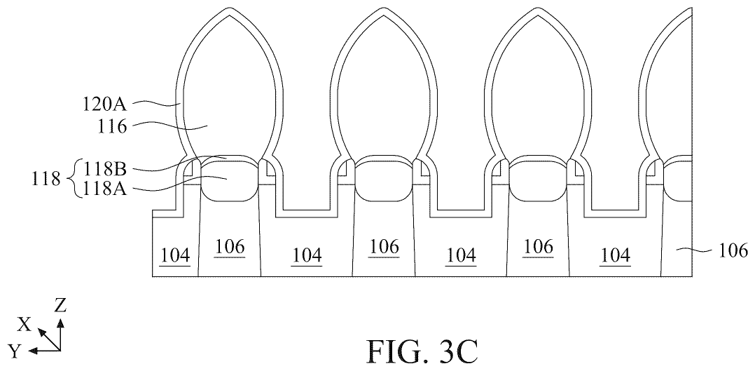

FIG. 2 is a flow diagram of an example method 200 for fabricating GAA FET 100 as described above with reference to FIGS. 1A-1H, according to some embodiments. For illustrative purposes, the operations illustrated in FIG. 2 will be described with reference to the example fabrication process for fabricating GAA FET 100 as illustrated in FIGS. 3A-14A, 3B-14B, 3C-14C, 15, and 16. FIGS. 3A-14A are isometric views of GAA FET 100 at various stages of fabrication, according to some embodiments. FIGS. 3B-14B, 15, and 16 are cross-sectional views of GAA FET 100 along line A-A of FIG. 1A at various stages of fabrication, according to some embodiments. FIGS. 3C-14C are cross-sectional views of GAA FET 100 along line B-B of FIG. 1A at various stages of fabrication, according to some embodiments. Operations can be performed in a different order or not performed depending on specific applications. It should be noted that method 200 may not produce a complete GAA FET 100. Accordingly, it is understood that additional processes can be provided before, during, and after method 200, and that some other processes may only be briefly described herein. The discussion of elements in FIGS. 1A-1H, 3A-14A, 3B-14B, 3C-14C, 15, and 16 with the same annotations applies to each other, unless mentioned otherwise.

Referring to FIG. 2, in operation 205, superlattice structures are formed on fin-shaped base structures and polysilicon structures and outer gate spacers are formed on the superlattice structures. For example, as described with reference to FIGS. 3A-3C, superlattice structures 309 (also referred to as “nanosheet stack 309”) are formed on fin-shaped base structures 106, and polysilicon structures 310 are formed on superlattice structure 309. Superlattice structures 309 and polysilicon structures 310 are not visible in cross-sectional view of FIG. 3C. In some embodiments, hard mask layers 332 and 334 can be formed during the formation of polysilicon structures 310. Superlattice structures 309 can include nanostructured layers 108A-108C and sacrificial nanostructured layers 308 arranged in an alternating configuration. In some embodiments, nanostructured layers 108A-108C can include Si and sacrificial nanostructured layers 308 can include SiGe. In some embodiments, each of nanostructured layers 108A-108C and sacrificial nanostructured layers 308 can have a thickness of about 3 nm to about 15 nm along a Z-axis. During subsequent processing, polysilicon structures 310 and sacrificial nanostructured layers 308 can be replaced with gate structures 110 in a gate replacement process.

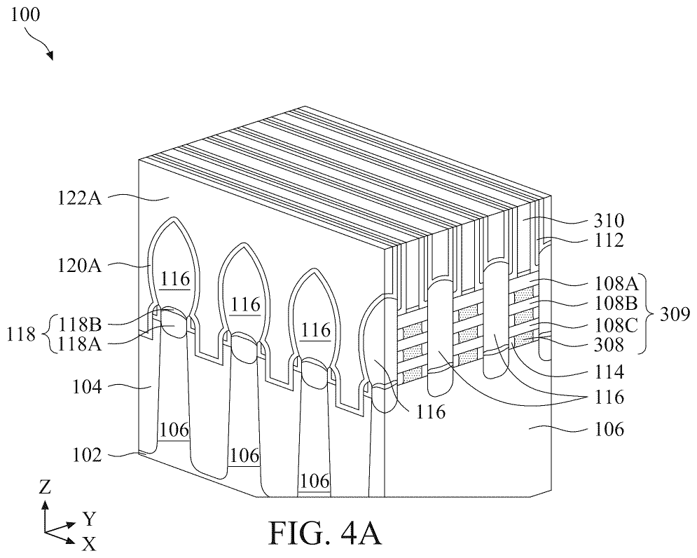

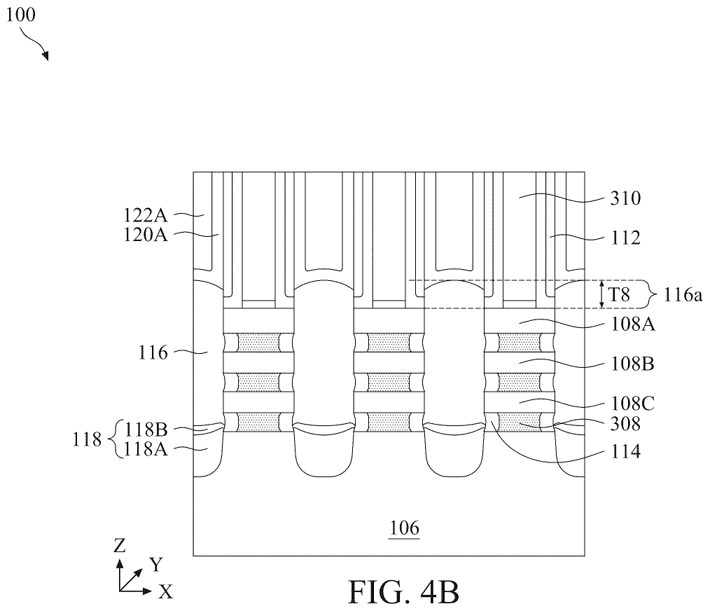

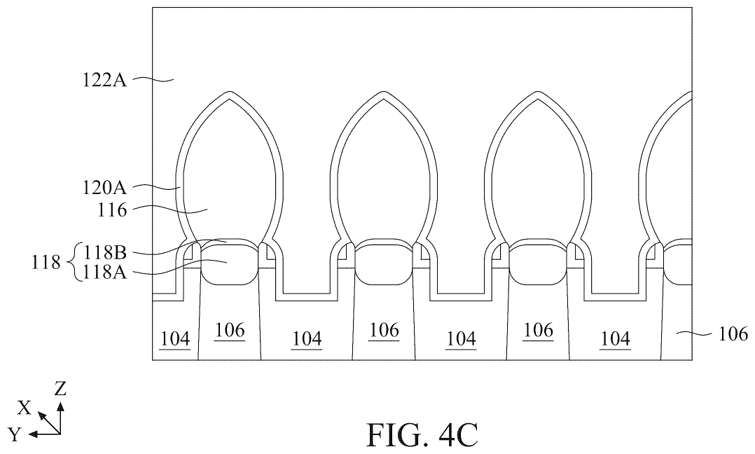

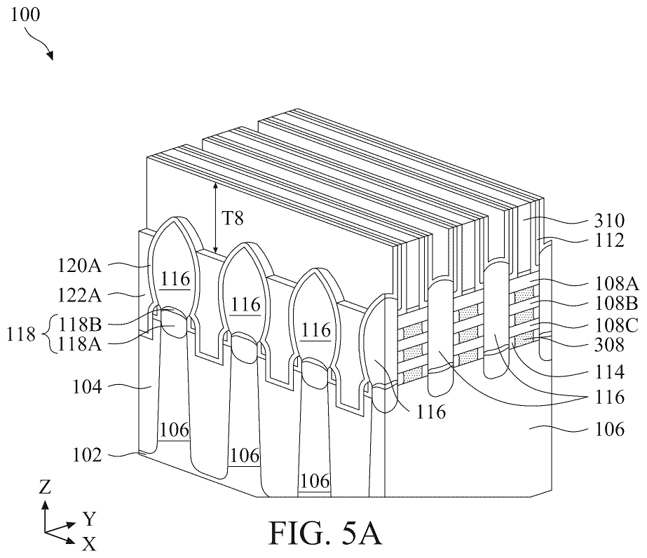

Referring to FIG. 2, in operation 210, inner gate spacers and S/D regions are formed in the superlattice structures. For example, as described with reference to FIGS. 3A-3C, inner gate spacers 114 and S/D regions 116 are formed in superlattice structures 309. Inner gate spacers 114 not visible in cross-sectional view of FIG. 3C. In some embodiments, S/D openings (not shown) can be formed in superlattice structures 309, which can be followed by the formation of isolation trenches (not shown) in fin-shaped base structures 106. The formation of isolation trenches can be followed by the formation of inner gate spacers 114 along sidewalls of sacrificial nanostructured layers 308. as shown in FIGS. 3A and 3B. The formation of inner gate spacers 114 can be followed by the formation of interposing layers 118 in the isolation trenches, which can be followed by the epitaxial growth of S/D regions 116 in the S/D openings. In some embodiments, S/D regions 116 can extend above superlattice structures 309 and the extended S/D portions 116a can be formed with a thickness T8 of about 4 nm to about 12 nm, as shown in FIG. 3B. The formation of S/D regions 116 can be followed by the formation of ESLs 120A and ILD layers 122A on S/D regions 116, as shown in FIGS. 4A-4C.

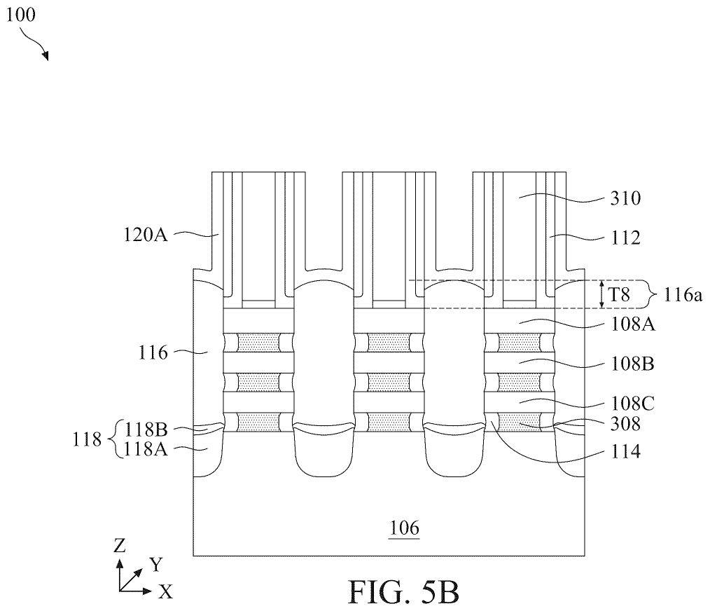

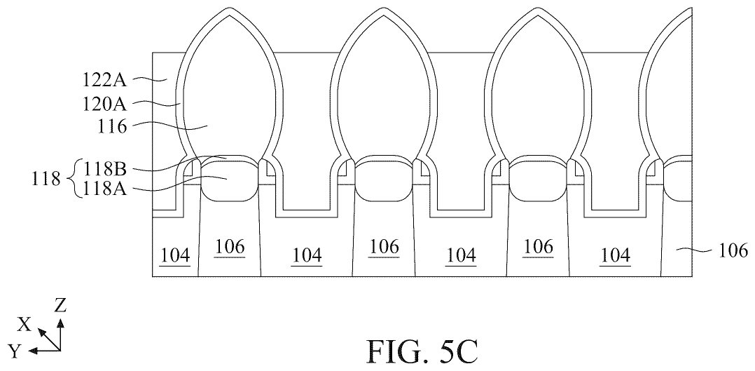

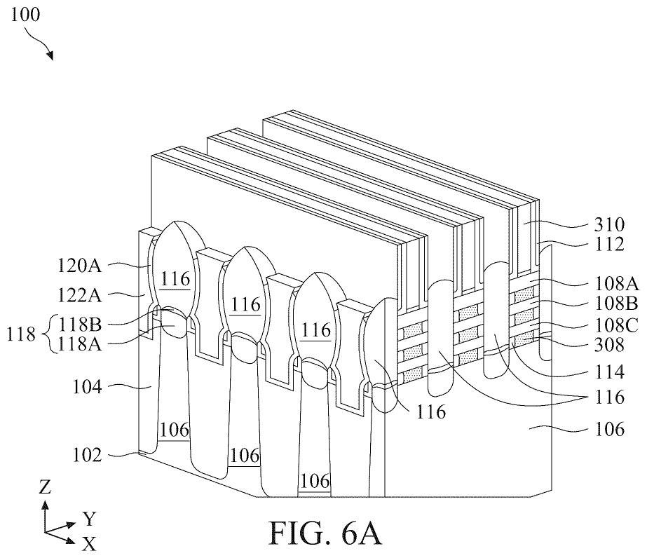

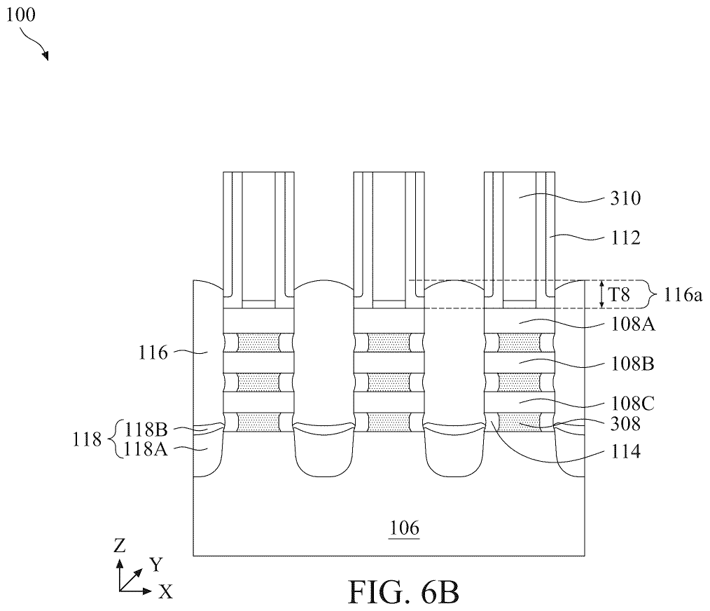

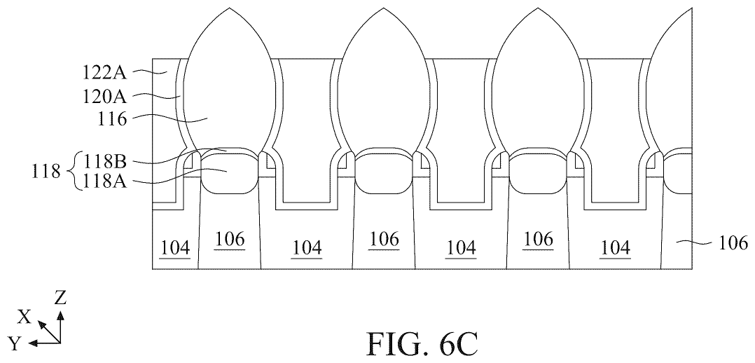

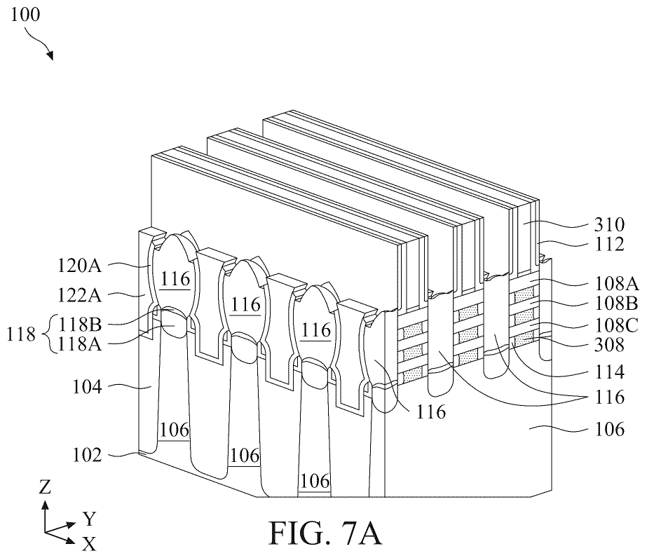

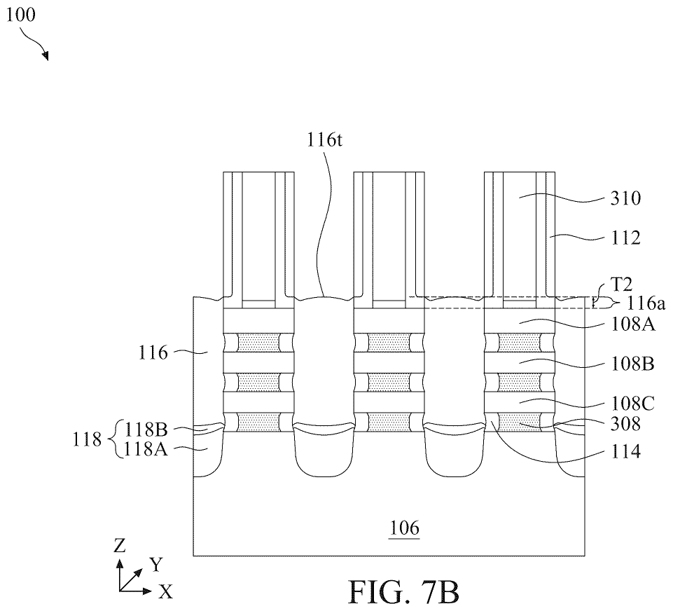

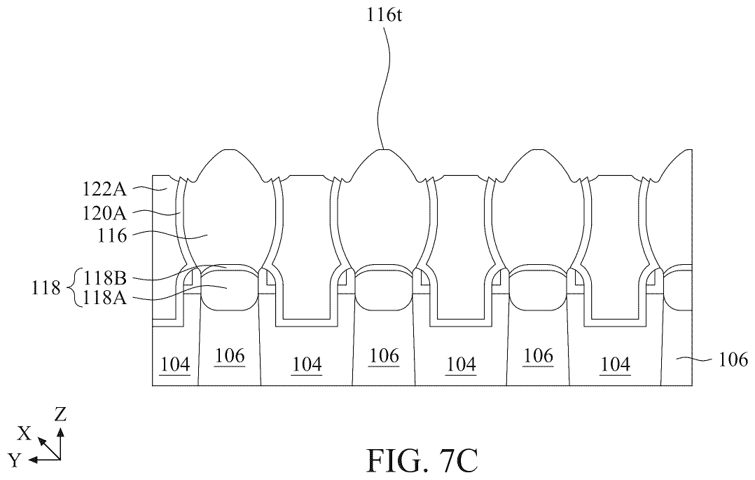

Referring to FIG. 2, in operation 215, portions of the S/D regions extending above the superlattice structures are modified. For example, as described with reference to FIGS. 5A-7A, 5B-7B, and 5C-7C, extended S/D portions 116a can be modified to reduce their thicknesses from thickness T8 to thickness T2. In some embodiments, the modification of extended S/D portions 116a can include sequential operations of (i) performing a first etching process on the structures of FIGS. 4A-4C to remove portions of ILD layers 122A and expose portions of ESLs 120A on extended S/D portions 116a, as shown in FIGS. 5A-5C, (ii) performing a second etching process on the structures of FIGS. 5A-5C to remove the exposed portions of ESLs 120A and expose extended S/D portions 116a, as shown in FIGS. 6A-6C, and (iii) performing a third etching process on the structures of FIGS. 6A-6C to etch extended S/D portions 116a and reduce their thicknesses from thickness T8 to thickness T2, as shown in FIGS. 7A-7C. In some embodiments, the third etching process can include a dry etching process using etching gases, such as carbon tetrafluoride (CF₄) and nitrogen trifluoride (NF₃) with mixture gases, such as hydrogen (H₂) and argon (Ar). In some embodiments, the third etching process can include a wet etching process using a mixture of ammonia hydroxide (NH₄OH) with H₂O₂ and deionized (DI) water. In some embodiments, depending on the etching parameters of the third etching process, S/D top surfaces 116t of extended S/D portions 116a can be formed with W-shaped cross-sectional profiles, as shown in FIGS. 7A-7C or can be formed with concave-shaped cross-sectional profiles, as shown in FIGS. 1E-1G.

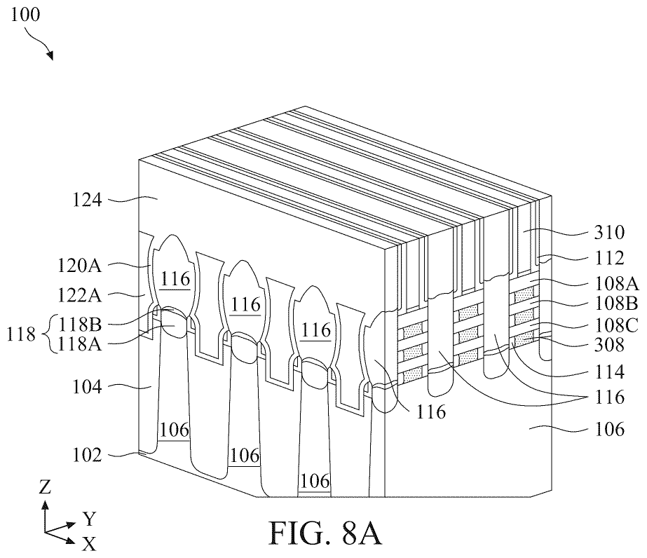

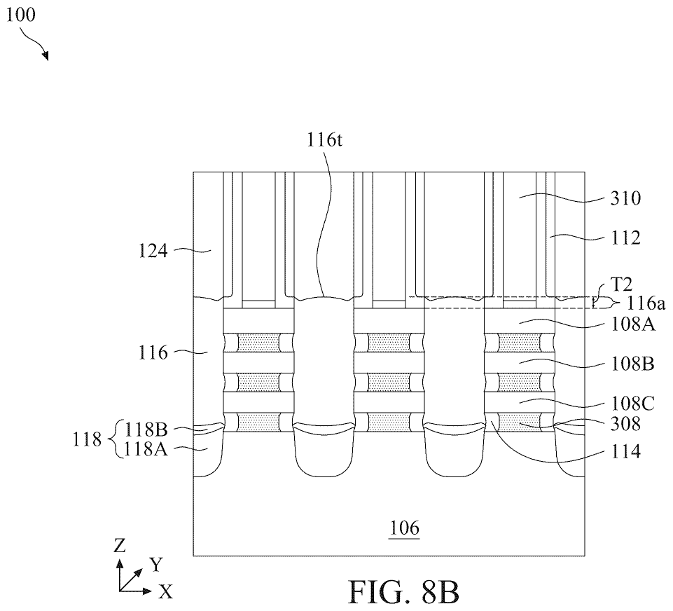

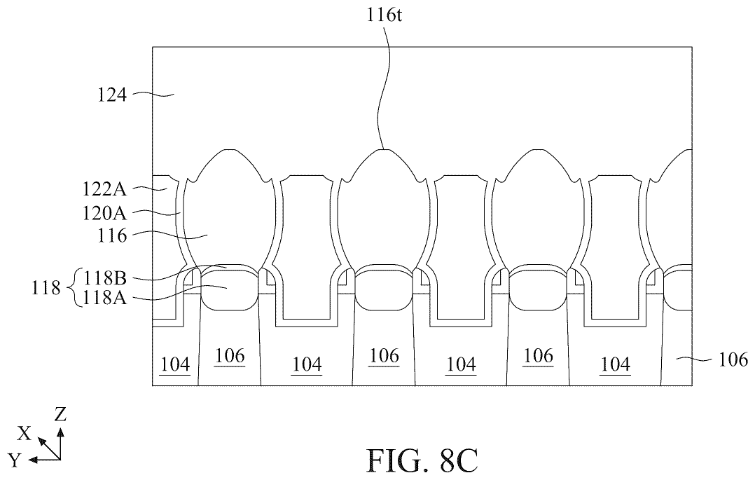

Referring to FIG. 2, in operation 220, etch control layers are formed on the modified portions of the S/D regions. For example, as described with reference to FIGS. 8A-8C, etch control layers 124 are formed on extended S/D portions 116a that are modified. The formation of etch control layers 124 can include sequential operations of (i) depositing a dielectric nitride layer (e.g., SiN layer, not shown) on the structures of FIGS. 7A-7C, and (ii) performing a chemical mechanical polishing (CMP) process on the dielectric nitride layer to form the structures of FIGS. 8A-8C. In some embodiments, after the CM P process, top surfaces of etch control layers 124, outer gate spacers 112, and polysilicon structures 310 can be substantially coplanar with each other.

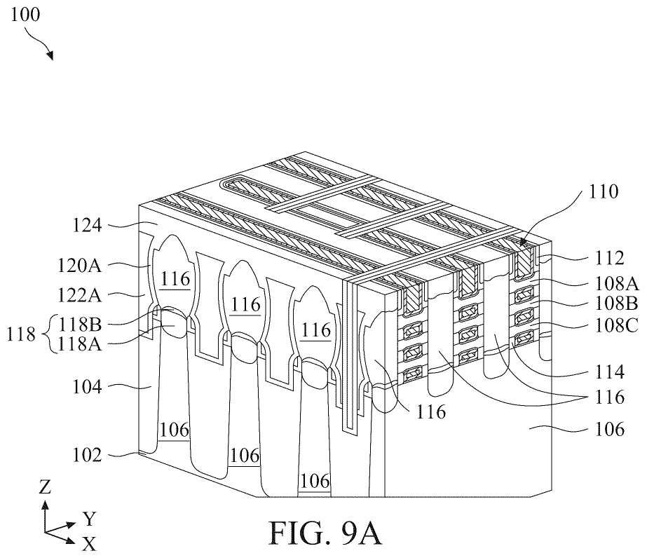

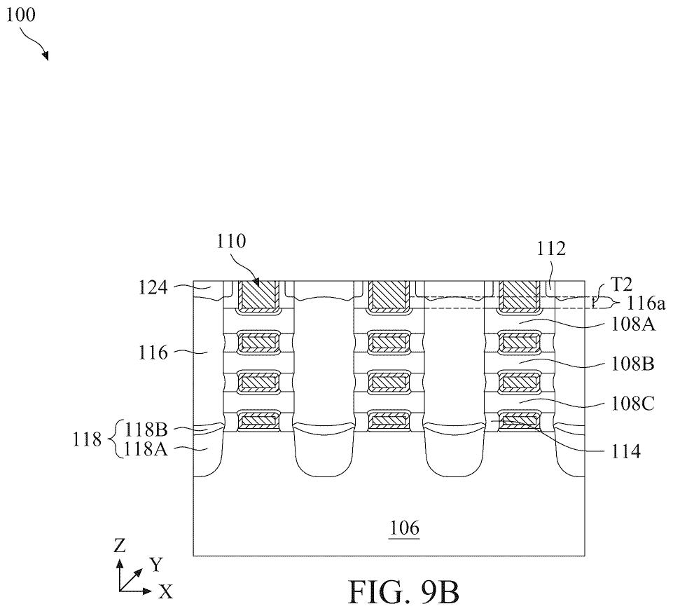

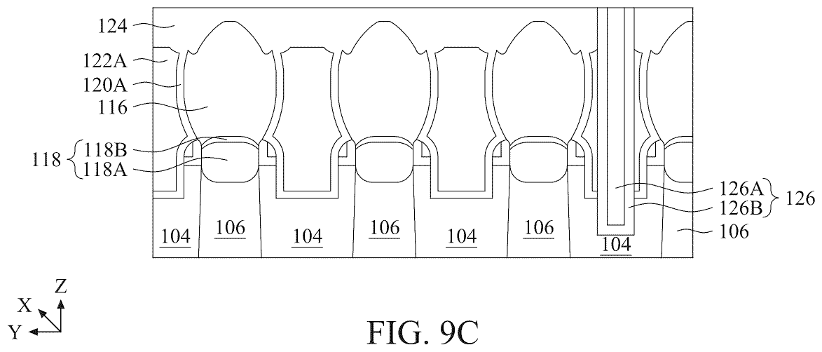

Referring to FIG. 2, in operation 225, the polysilicon structures and sacrificial nanostructured layers of the superlattice structures are replaced with gate structures. For example, as described with reference to FIGS. 9A-9C, polysilicon structures 310 and sacrificial nanostructured layers 308 are replaced with gate structures 110 (not visible in cross-sectional view of FIG. 9C). The formation of gate structures 110 can include removing polysilicon structures 310 and sacrificial nanostructured layers 308 from the structures of FIGS. 8A and 8B to form gate openings (not shown), and forming gate structures 110 in the gate openings, as shown in FIGS. 9A and 9B. In some embodiments, top surfaces of etch control layers 124, outer gate spacers 112, and gate structures 110 can be substantially coplanar with each other. In some embodiments, the formation of gate structures 110 can be followed by the formation of device isolation structures 126, as shown in FIGS. 9A and 9C (device isolation structures 126 not visible in cross-sectional view of FIG. 9B). The formation of device isolation structures 126 can be followed by the deposition of ESLs 120B, ILD layers 122B, and a hard mask layer 1036 on the structures of FIGS. 9A-9C. In some embodiments, hard mask layer 1036 can include a tungsten carbide (WC) layer.

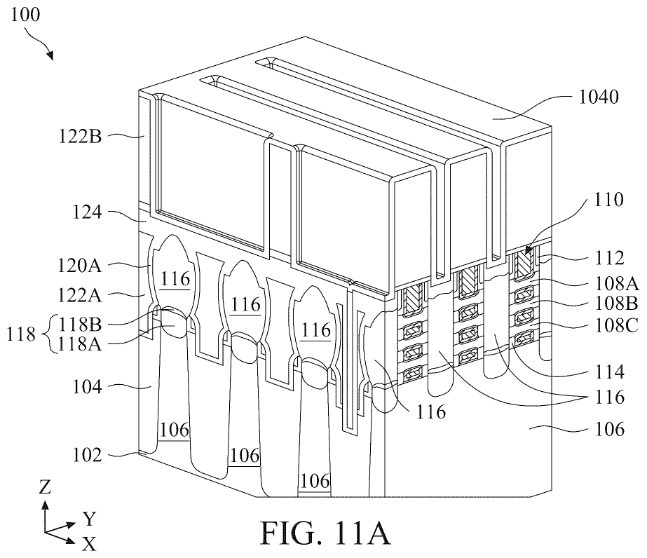

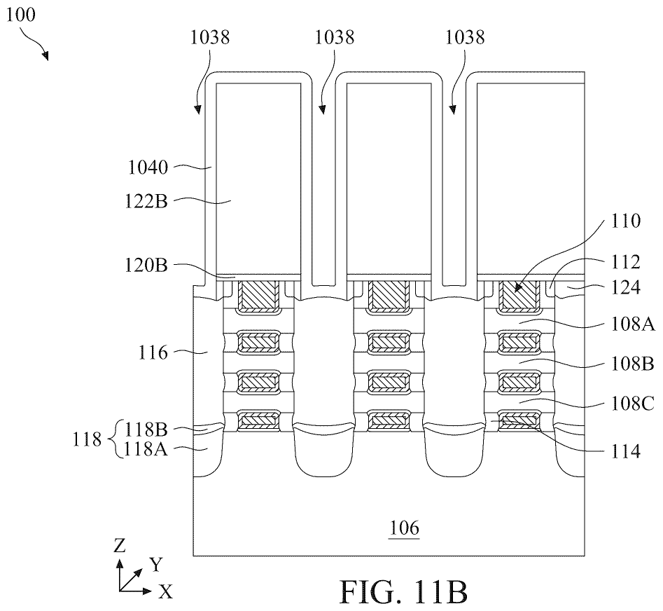

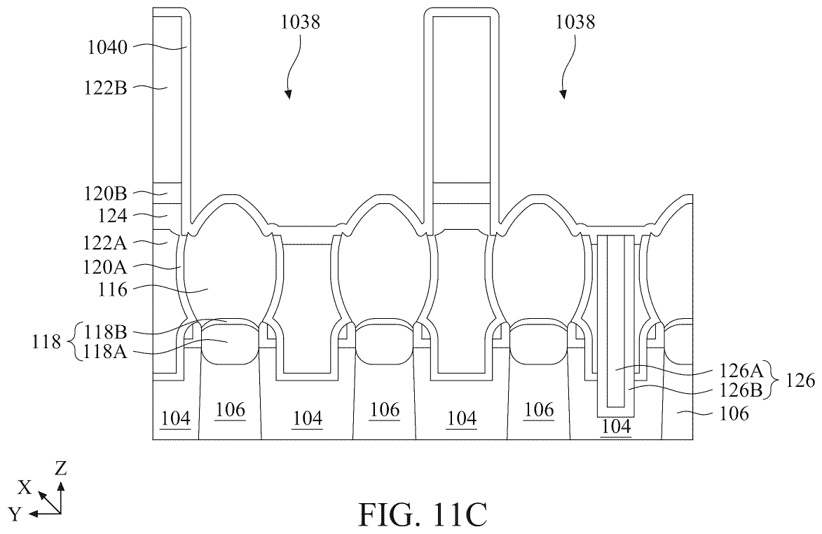

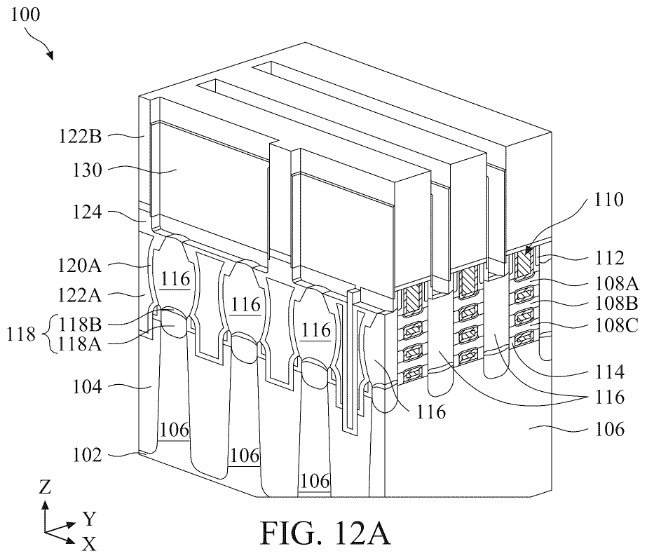

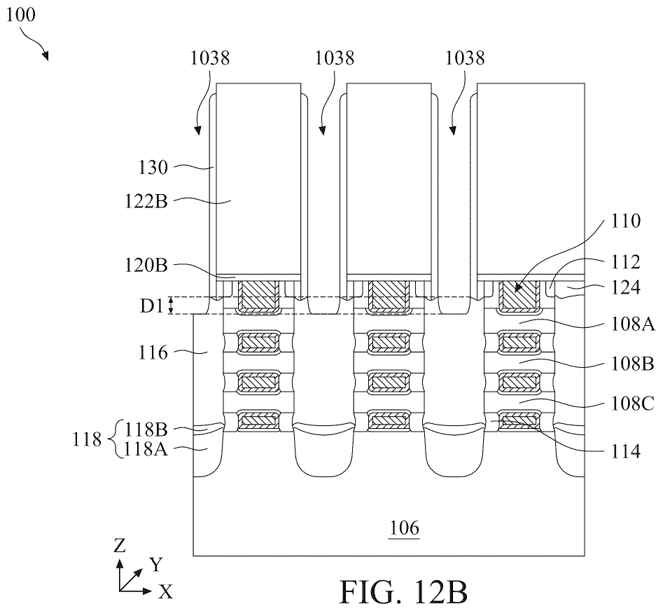

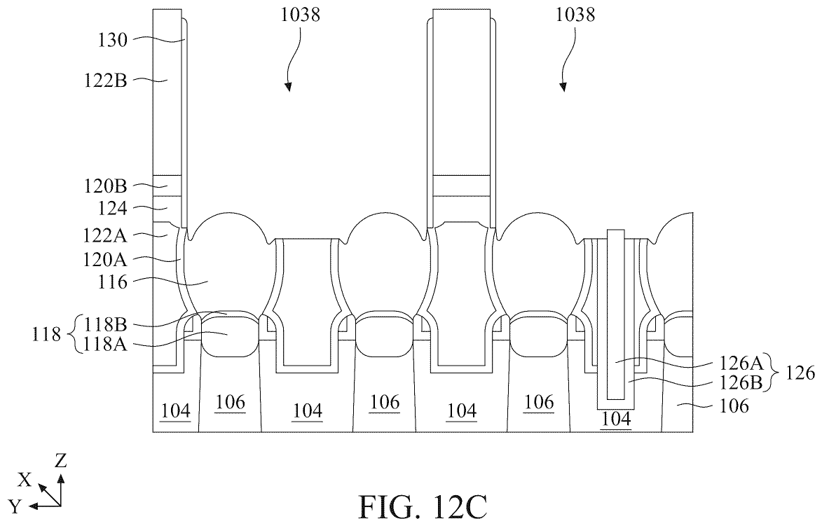

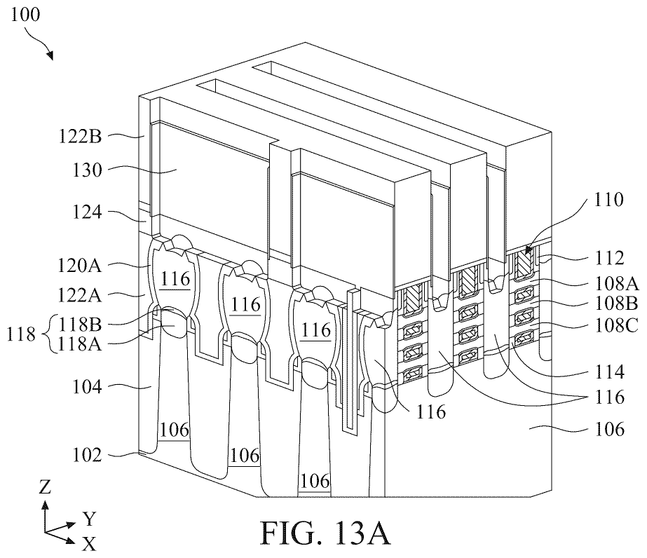

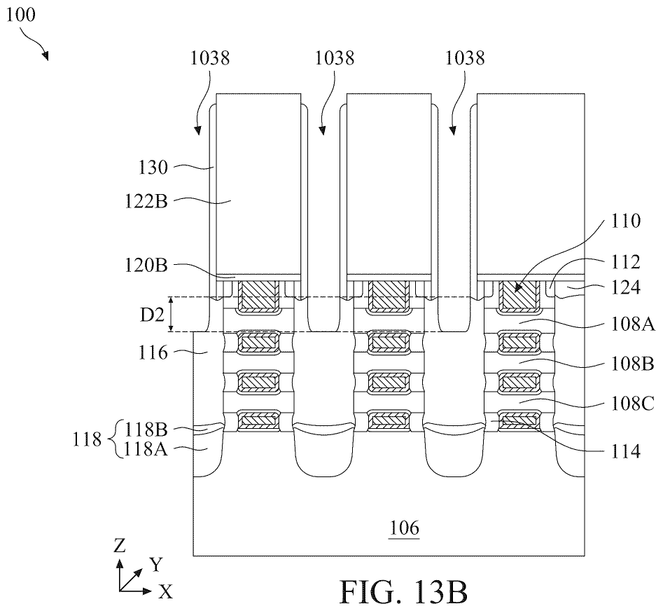

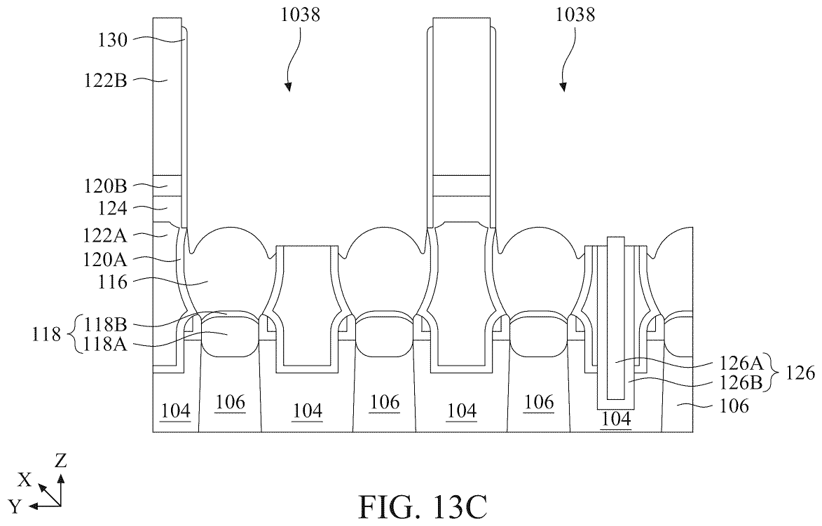

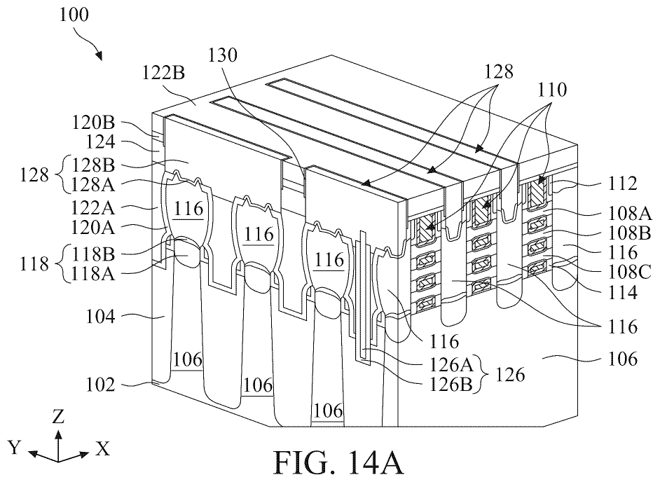

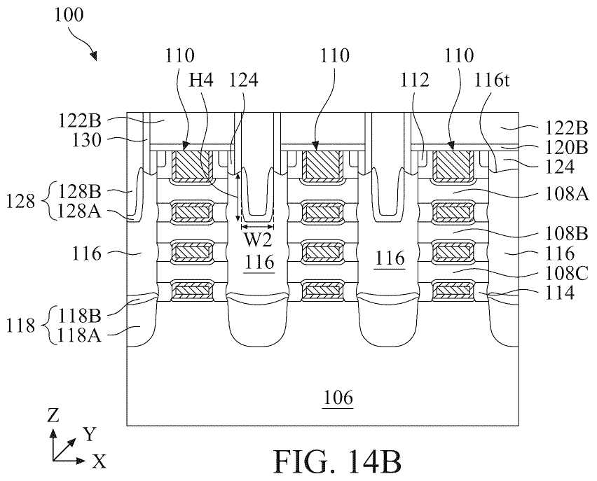

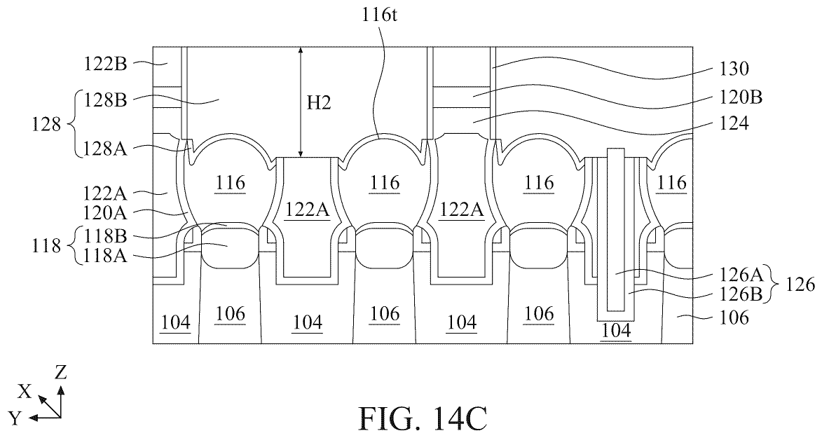

Referring to FIG. 2, in operation 230, contact structures are formed on the S/D regions. For example, as described with reference to FIGS. 10A-14A, 10B-14B, and 10C-14C, contact structures 1128 are formed on S/D regions 116. The formation of contact structures 128 can include sequential operations of (i) performing a first etching process to remove portions of hard mask layer 1036, ILD layers 122B, ESLs 120B and etch control layers 124 on S/D regions 116 to form contact openings 1038 on S/D regions 116, as shown in FIGS. 10A-10C, (ii) removing hard mask layer 1036 (not shown), (iii) depositing a dielectric nitride layer 1040 on top surfaces of ILD layers 122B and on the exposed surfaces of ILD layers 122B, ESLs 120B, etch control layers 124, ILD layers 122A, ESLs 120A, and S/D regions 116 in contact openings 1038, as shown in FIGS. 11A-11C, (iv) performing a second etching process on the structures of FIGS. 11A-11C to form dielectric layers 130 and to extend contact openings 1038 into S/D regions 116 by a depth D1, as shown in FIGS. 12A-12C, (v) performing a third etching process on exposed S/D regions 116 in contact openings 1038 to increase the depth of contact openings 1038 from depth D1 to depth D2, as shown in FIGS. 13A-13C, (vi) forming silicide layers 128A in contact openings 1038, as shown in FIGS. 14A-14C, and (vii) forming conductive layers 128B on silicide layers 128A, as shown in FIGS. 14A-14C. In some embodiments, after the formation of conductive layers 128B, top surfaces of conductive layers 128B, ILD layers 122B, and dielectric layers 130 can be substantially coplanar with each other.

In some embodiments, the second etching process can include a dry etching process using etching gases, such as fluoromethane (CH₃F), hexafluorocyclobutene (C₄F₆) and carbonyl sulfide (COS) with mixture gases, such as H₂ and nitrogen (N₂), which can be followed by a post-clean process using deionized (DI) water. In some embodiments, the third etching process can include a dry etching process using an etching gas, such as CF₄ and with a mixture gas, such as Ar, which can be followed by a post-clean process using hydrofluoric (HF) solution.

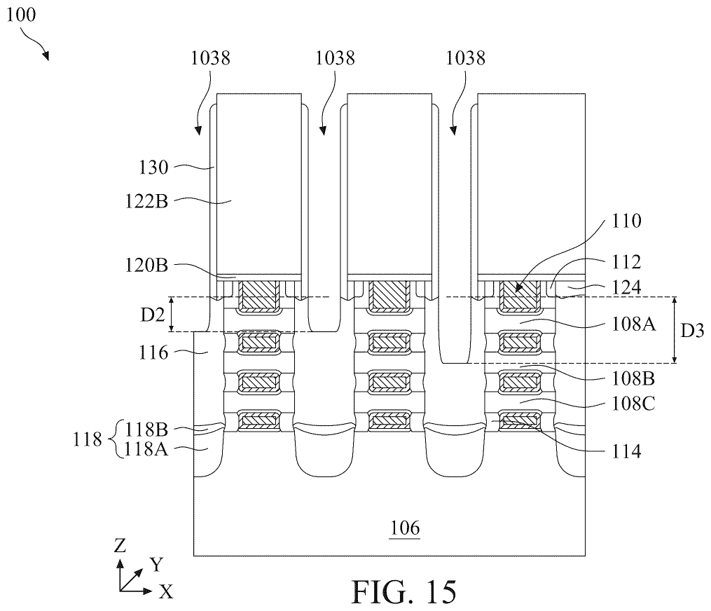

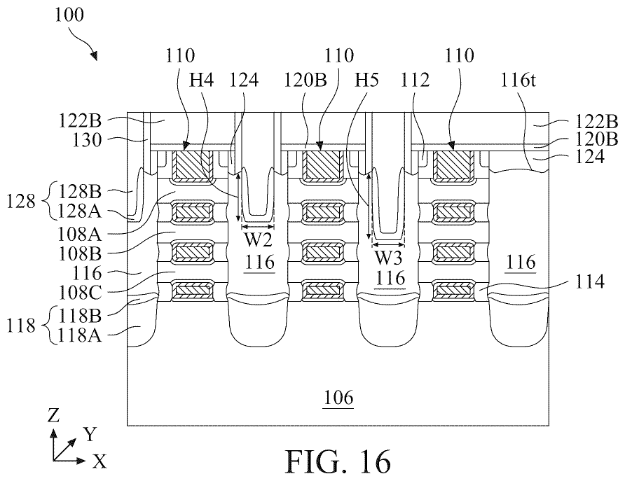

In some embodiments, GAA FET 100 with the cross-sectional view of FIG. 1H can be formed with method 200, except in operation 230, (i) the third etching process can be followed by a fourth etching process on one or more S/D regions 116 to increase the depth of one or more contact openings 1038 from depth D2 to depth D3, as shown in FIG. 15, and (ii) silicide layers 128A and conductive layers 128B can be formed in contact openings 1038 of FIG. 15 to form the structure of FIG. 16. In some embodiments, the fourth etching process can include a dry etching process using an etching gas, such as CF₄ and with a mixture gas, such as Ar, which can be followed by a post-clean process using HF solution.

The present disclosure provides example GAA FETs (e.g., GAA FET 100) with reduced parasitic capacitance between a gate structure and a S/D region and examples methods of fabricating these GAA FETs. In some embodiments, the formation of the S/D region (e.g., S/D regions 116) can be followed by an etching process on the S/D region to reduce the thickness of the extended S/D portion (e.g., extended S/D portions 116a) without compromising the sidewall coverage of the nanostructured channel regions (nanostructured channel regions 108A-108C) by the S/D region. In some embodiments, to ensure adequate sidewall coverage of the nanostructured channel regions by the S/D region, the etching process can be controlled to achieve W-shaped or concave-shaped cross-sectional profiles along vertical cross-sectional planes (e.g., XZ and YZ planes) for the S/D top surface (e.g., S/D top surfaces 116t). In some embodiments, for the W-shaped or concave-shaped cross-sectional profiles of the S/D top surface extending between adjacent nanostructured channel regions, the edges of the S/D top surface can be raised above the top surfaces of the topmost nanostructured channel regions (e.g., topmost nanostructured channel regions 108A) and the middle portion of the S/D top surface can have a convex-shaped or a concave-shaped profile. In some embodiments, during the etching process, the thickness of the extended S/D portion can be reduced from a first thickness (e.g., thickness T8) of about 4 nm to about 12 nm to a second thickness (e.g., thickness T2) of about 2 nm to about 8 nm. Such reduction in the thickness of the extended S/D portion can result in the reduction of the parasitic capacitance between the S/D region and the gate structures by about 2% to about 3%. In some embodiments, reducing the thickness of the extended S/D portion can also facilitate the formation of gate structures with shorter heights (e.g., height H1), which facilitates the scaling down of GAA FETs to meet the increasing demand for small and portable semiconductor devices.

In some embodiments, the etching process can be followed by the formation of a etch control layer (e.g., etch control layers 124) on the S/D top surface and on top surfaces of an ESL (e.g., ESLs 120A) and ILD layer (e.g., ILD layers 122A) disposed on the S/D region. The etch control layer can preserve the integrity of the edge profiles of the S/D top surface during subsequent processes on the S/D region. In some embodiments, the etch control layer can also facilitate the formation of deep contact opening (e.g., contact openings 1038) in the S/D region while preventing the ESL and ILD layer from being over-etched during the formation of the contact opening. As a result, a contact structure (e.g., contact structures 128) on the S/D region can be formed with a larger contact area with the S/D region, while the portion of the contact structure on the ESL and ILD layer can have a depth less than that formed without the barrier layer on the S/D region. In some embodiments, due to such shallow depth of the contact structure, the parasitic capacitance between the S/D region and the portion of the contact structure on the ESL and ILD layer can be reduced by about 1% to about 4%. Thus, the overall parasitic capacitance of the GAA FET can be reduced by about 3% to about 7%.

In some embodiments, a method includes forming a superlattice structure with a nanostructured layer and a sacrificial nanostructured layer on a base structure on a substrate, forming a polysilicon structure on the superlattice structure, and forming a S/D region in the superlattice structure. A S/D portion of the S/D region extends above the nanostructured layer. The method further includes modifying a thickness of the S/D portion, depositing a dielectric layer on the modified S/D portion, and replacing the polysilicon structure and the sacrificial nanostructured layer with a gate structure.

In some embodiments, a method includes forming a stack of nanostructured layer and sacrificial nanostructured layer on a base structure on a substrate, forming a polysilicon structure surrounding the stack of nanostructured layer and sacrificial nanostructured layer, epitaxially growing a S/D region adjacent to the nanostructured layer, modifying a cross-sectional profile of a S/D portion of the S/D region that extends above the nanostructured layer, and replacing the polysilicon structure and the sacrificial nanostructured layer with a gate structure.

In some embodiments, a semiconductor device includes a substrate, a nanostructured channel region disposed on the substrate, and a S/D region disposed adjacent to the nanostructured channel region. A S/D portion of the S/D region extends above the nanostructured layer and a top surface of the S/D portion includes a W-shaped or a concave-shaped cross-sectional profile. The semiconductor device further includes a first dielectric layer disposed on sidewalls of the S/D region and a second dielectric layer disposed on the top surface of the S/D portion and the first dielectric layer. Materials of the first and second dielectric layers are different from each other.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a superlattice structure with a nanostructured layer and a sacrificial nanostructured layer on a base structure on a substrate;
forming a polysilicon structure on the superlattice structure;
forming a source/drain region in the superlattice structure, wherein a source/drain portion of the source/drain region extends above the nanostructured layer;
modifying a thickness of the source/drain portion;
depositing a dielectric layer on the modified source/drain portion; and
replacing the polysilicon structure and the sacrificial nanostructured layer with a gate structure.

2. The method of claim 1, wherein modifying the thickness of the source/drain portion comprises performing an etching process on the source/drain portion.

3. The method of claim 1, wherein modifying the thickness of the source/drain portion comprises reducing the thickness of the source/drain portion.

4. The method of claim 1, further comprising depositing an etch stop layer on the source/drain region prior to modifying the thickness of the source/drain portion.

5. The method of claim 4, wherein modifying the thickness of the source/drain portion comprises etching the etch stop layer to expose the source/drain portion.

6. The method of claim 1, wherein depositing the dielectric layer comprises depositing a silicon nitride layer on the modified source/drain portion.

7. The method of claim 1, wherein modifying the thickness of the source/drain portion comprises modifying a cross-sectional profile of a top surface of the source/drain portion.

8. The method of claim 1, further comprising forming a silicide layer in the source/drain region, wherein the silicide layer comprises:
a W-shaped cross-sectional profile along a first cross-sectional plane; and
a U-shaped cross-sectional profile along a second cross-sectional plane.

9. The method of claim 1, further comprising:
performing a first etching process on the source/drain to form a contact opening in the source/drain region; and
performing a second etching process on the source/drain to increase a depth of the contact opening in the source/drain region.

10. The method of claim 9, further comprising:
forming a silicide layer in the contact opening after the second etching process; and
depositing a conductive layer on the silicide layer.

11. A method, comprising:
forming a stack of a nanostructured layer and a sacrificial nanostructured layer on a base structure on a substrate;
forming a polysilicon structure surrounding the stack of the nanostructured layer and the sacrificial nanostructured layer;
epitaxially growing a source/drain region adjacent to the nanostructured layer;
modifying a cross-sectional profile of a source/drain portion of the source/drain region that extends above the nanostructured layer; and
replacing the polysilicon structure and the sacrificial nanostructured layer with a gate structure.

12. The method of claim 11, wherein modifying the cross-sectional profile of the source/drain portion comprises converting a top surface of the source/drain portion from a convex-shaped cross-sectional profile to a W-shaped cross-sectional profile or a concave-shaped cross-sectional profile.

13. The method of claim 11, wherein modifying the cross-sectional profile of the source/drain portion comprises performing an etching process on the source/drain portion.

14. The method of claim 11, further comprising:
forming a contact opening with a first opening on the source/drain region and a second opening in the source/drain region;
forming a silicide layer in the second opening; and
depositing a conductive layer in the first and second openings.

15. The method of claim 14, further comprising forming a dielectric layer along sidewalls of the first opening prior to forming the silicide layer.

16. The method of claim 11, further comprising depositing a nitride layer on the modified cross-sectional profile of the source/drain portion prior to replacing the polysilicon structure and the sacrificial nanostructured layer.

17. A semiconductor device, comprising:
a substrate;
a nanostructured channel region disposed on the substrate;
a source/drain region disposed adjacent to the nanostructured channel region, wherein a source/drain portion of the source/drain region extends above the nanostructured channel region. and wherein a top surface of the source/drain portion comprises a W-shaped or a concave-shaped cross-sectional profile;
a first dielectric layer disposed on sidewalls of the source/drain region; and
a second dielectric layer disposed on the top surface of the source/drain portion and the first dielectric layer, wherein materials of the first and second dielectric layers are different from each other.

18. The semiconductor device of claim 17, further comprising a silicide layer disposed in the source/drain region, wherein the silicide layer comprises:
a W-shaped cross-sectional profile along a first cross-sectional plane; and
a U-shaped cross-sectional profile along a second cross-sectional plane.

19. The semiconductor device of claim 17, further comprising:
a contact structure comprising a first contact portion disposed in the source/drain region and a second contact portion disposed on the source/drain region; and
a third dielectric layer surrounding the second contact portion.

20. The semiconductor device of claim 19, further comprising an etch stop layer surrounding the third dielectric layer.
